(19) United States
(12) Patent Application Publication
(10) Pub. No.: US 2026/0051337 A1
(43) Pub. Date: Feb. 19, 2026

(54) CONFIGURABLE MEMORY INTEGRATED CIRCUIT PINS

(71) Applicant: Advanced Micro Devices, Inc., Santa Clara, CA (US)

(72) Inventors: Aaron John NYGREN, Boise, ID (US); Anwar KASHEM, Sudbury, MA (US); Edoardo PRETE, Boxborough, MA (US); Christopher Edward COX, Folsom, CA (US)

(21) Appl. No.: 19/301,101

(22) Filed: Aug. 15, 2025

Related U.S. Application Data
(60) Provisional application No. 63/683,661, filed on Aug. 15, 2024.

(51) Int. Cl. G11C 5/06; G11C 8/06; H01L 25/18; H10B 80/00; H10D 80/30

(52) U.S. Cl. CPC G11C 5/06; G11C 8/06; H01L 25/18; H10B 80/00; H10D 80/30

(57) ABSTRACT

An electronic device includes a host device comprising memory controller circuitry and a memory IC device connected to the memory controller circuitry. The memory IC device includes memory devices and pins connected to the memory devices and the memory controller circuitry. The pins route signals to and from the memory devices. The pins are configurable based on configuration data to perform memory operations.

### CROSS REFERENCE TO RELATED APPLICATIONS

This application claims the benefit of U.S. provisional patent application Ser. No. 63/683,661, filed Aug. 15, 2024, which is hereby incorporated herein by reference.

### TECHNICAL FIELD

Examples of the present disclosure generally relate to configurable input/output pins of a memory integrated circuit device.

### BACKGROUND

Memory integrated circuit (IC) devices are connected with integrated circuit (IC) devices via traces that connect pins of the memory IC devices with pins of the IC devices. The traces and pins may be referred to as an interface. As memory device technology advances, adding more pins for additional functionality and/or reducing the circuit area available to place pins, the circuit area available for pins (e.g., data and clock pins) of a memory device is decreasing, increasing the density of the pins and/or limiting the number of pins that may be included. As the circuit area available for the data and clock pins decreases, the overhead associated with the clock pins increases. Further, pins have been added to the interface to support functions including link protection and communicating metadata, driving the pin count higher.

A memory IC device may be a native memory IC device or a buffered memory IC device. A native memory IC device does not have buffers between the individual memory devices (or circuitries) of the memory IC device and the IC device. A buffered memory IC device includes one or more buffers between the individual memory devices of the memory IC device and the IC device. The buffers are used to buffer and re-time one or more signals communicated between the IC device and the memory IC device. In a native memory IC device, the memory devices are directly connected to the IC device and there are independent clock signals associated with the data signal. Accordingly, the number of pins used by an interface between an IC device and a native mode memory IC device is very high. In a buffered memory IC device, one or more buffers are included within the memory IC device and signals provided to a buffered memory IC device may be consolidated and there may be a greater number of data pins per clock pin as compared to a native mode memory IC device. Typically, a memory IC device is built to be either a buffer memory IC device or a native memory IC device, increasing the different configurations of memory IC devices that are designed and manufactured, increasing the design time and semiconductor manufacturing costs for the memory IC devices.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates a block diagram of an electronic device having configurable pins of a memory integrated circuit device.

FIG. 2 illustrates a block diagram of an electronic device having configurable pins of a memory integrated circuit device.

FIG. 3 illustrates a block diagram of a computer system.

FIG. 4 illustrates a flowchart of a method for configuring pins of a memory integrated circuit device.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

An electronic device includes a host device and a memory integrated circuit (IC) device or devices. The host device interacts (reads data from and write data to) with (reads data from and write data to) the memory IC device to perform one or more functions or operations of the electronic device. The memory IC device is connected to the host device via an interconnect circuitry. The interconnect circuitry includes pins within the memory IC device and pins within the host device, which are interconnected via wires.

The host device outputs control signals and data signals to the memory IC device to write data to the memory IC device and/or read data from the memory IC devices via interconnect circuitry. The signals output from the host device are received and routed within the memory IC device to perform the corresponding read command or write command.

A memory integrated circuit (IC) device includes one or more memory devices (circuitries). The memory devices are used to store data within the memory IC device. The memory device includes memory cells that store data. The memory cells include one or more capacitors and transistors, which are used to store data and retrieve the stored data. In one example, the memory devices of a memory IC device are disposed in one or more rows and/or one or more columns. The memory devices are mounted to a substrate of the memory IC device. The memory devices may be mounted to either side of the substrate of the memory IC device.

A memory IC device may be configured in a native configuration or in a buffered configuration. In a native configuration, the memory devices are connected to input/output (I/O) pins (or pins) of the memory IC device, which are then connected to corresponding pins of the host device. In a native configuration, buffers are not used between the memory devices and the host device. In a buffered memory IC device, one or more buffers are disposed within the memory IC device and are connected between the memory devices and the pins of the memory IC device. Accordingly, one or more signals communicated between the host device and the memory IC devices are received by the buffer (or buffers) before being routed to the memory devices.

In a native configuration, the memory devices are directly connected to the corresponding pins of the memory IC device (e.g., connected without the use of one or more buffers). Accordingly, a large number of pins are used to support the communication of the data signals, clock signals, link protection signals, metadata signals, and/or other control signals between memory IC device and the host device in the native configuration. The large number of pins increases the corresponding size of the interconnect circuitry (or interface). Increasing the size of the interconnect circuitry increases the cost of the corresponding IC device (e.g., host device) and/or the memory IC device. Further, increasing the size of the interconnect circuitry may additionally, or alternatively, limit the maximum communication speed between the memory IC device and the host device.

The memory IC devices described in the following have configurable interconnect circuitry, where the functionality of one or more pins of the interconnect circuitry may be changed. In one or more examples, a configurable interface includes one or more pins that may be enabled or disabled. The pins of the interface may be configured based on the configuration mode (e.g., native configuration mode or buffered configuration mode) of the memory IC device. Using configurable pins, decreases the overall size of the interconnect circuitry (e.g., the amount of circuit area used for the pins of the interconnect circuitry), decreasing the corresponding semiconductor manufacturing cost of the memory IC device and/or corresponding host device.

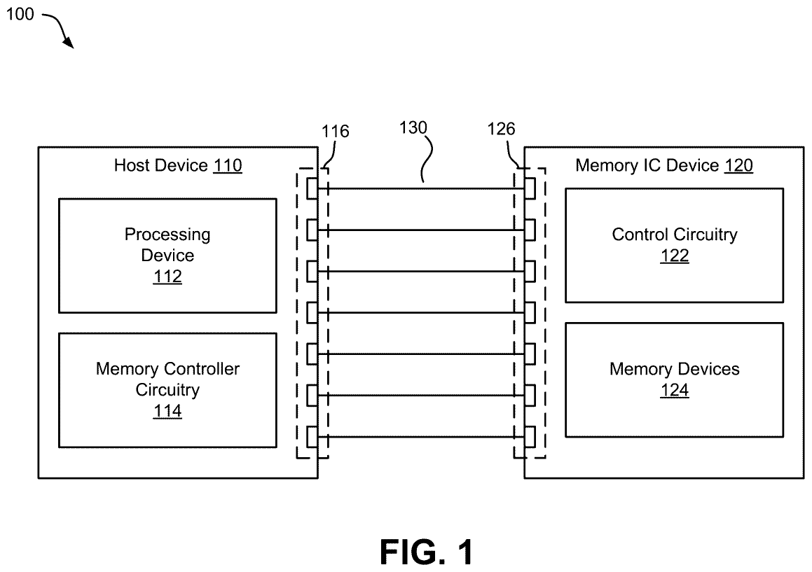

FIG. 1 illustrates a block diagram of an electronic device 100. In one or more examples, the electronic device 100 is a computer system. The electronic device 100 includes a host device 110 and the memory IC device 120. The host device 110 is connected to the memory IC device 120 via the wires 130. The wires 130 are used to communicate data signals (e.g., DQ signals), strobe signals, and control signals between the host device 110 and the memory IC device 120.

The host device 110 is an IC device. The host device 110 includes a processing device 112, memory controller circuitry 114, pins 116. In one or more examples, the host device 110 is a system-on-chip (SoC). The processing device 112 is connected to the memory controller circuitry 114. In one example, the processing device 112 communicates control signals and/or data signals to the memory controller circuitry 114. The processing device 112 is a central processing unit (CPU), a graphics processing unit (GPU), digital signal processor (DSP), accelerator circuitry, or another type of processing device. In one example, the processing device 112 is representative of one or more processing devices that may be the same or different types of processing devices.

The pins 116 are conductive elements that function as input/output connections for the host device 110. The pins 116 are connected to the wires 130. In one example, the pins 116 are communicatively connected with interface circuitry (not illustrated) of the host device 110. The interface circuitry may be referred to as physical interface circuitry.

The memory controller circuitry 114 controls writing data to and reading data from the memory IC device 120. In one example, the memory controller circuitry 114 receives one or more data signals and/or one or more control signals from the processing device 112, and generates memory transactions (e.g., read transactions and/or write transactions) that are communicated to the memory IC device 120 via the wires 130. The memory controller circuitry 114 outputs signals via the pins 116 and receives signals via the pins 116.

The memory IC device 120 is a synchronous dynamic random-access memory (SRAM). In one or more examples, the memory IC device 120 is a double data rate (DDR) SRAM, or other type of SRAM. In one or more examples, the memory IC device 120 is first, second, third, fourth, or fifth, among other, generation DDR (e.g., DDR1, DDR2, DDR3, DDR4, or DDR5), another type of DDR memory. In other examples, the memory IC device 120 is another type of memory. The memory IC device 120 is packaged as a module. For example, the memory IC device 120 is packaged as a Dual In-line memory Module (DIMM). In one or more examples, the memory IC device 120 is packaged as a multi-ranked buffered (MR) DIMMs.

The memory IC device 120 includes memory devices 124. The memory devices 124 may be random access memory (RAM). For example, the memory devices 124 are dynamic RAM (DRAM). The memory devices 124 store data bits.

The memory IC device 120 includes pins 126. The pins 126 are conductive connection elements that connect the memory IC device 120 with the wires 130. The memory IC device 120 further includes control circuitry 122. The control circuitry 122 is communicatively connected to the memory controller circuitry 114 and the memory devices 124. The control circuitry 122 functions as interface circuitry for the memory IC device 120. For example, the control circuitry 122 receives signals from the host device 110 via the pins 126, and routes the signals to the memory devices 124.

The wires 130 are connected to the pins 116 of the host device 110 and pins 126 of the memory IC device 120. Each of the wires 130 is connected to a respective one of the pins 116 and the pins 126. The wires 130, the pins 116, and the pins 126 form interconnect circuitry.

The memory IC device 120 operates in a buffered configuration or a native configuration. In a buffered configuration (e.g., buffered mode), the control circuitry 122 of the memory IC device 120 includes one or more buffer circuitries and/or multiplexing registered clock driver (MRCD) circuitry. In buffered configuration, the memory devices 124 communicate with the host device 110 via the buffer circuitries and/or the MRCD circuitry of the control circuitry 122. In a native configuration (e.g., a native mode), the memory IC device 120 does not include the buffer circuitries 222. Further, in a native configuration, the control circuitry 122 of the memory IC device 120 may not include MRCD circuitry. In a native configuration, the memory devices 124 communicate with the host device 110 directly (e.g., without the use of buffer circuitries 222).

In a buffered configuration, the buffer circuitries of the control circuitry 122 control the communication of control signals, and/or data signals to the memory devices 124. The MRCD circuitry of the control circuitry 122 buffers the control signals (e.g., command address signals, chip select signals, and clock signals, among others) received from the memory controller circuitry 114. The MRCD circuitry of the memory controller circuitry 114 outputs the buffered signals to the buffer circuitries and/or the memory devices 124.

In one or more examples, for a memory IC device 120 in a buffered configuration, the number of the pins 126 used to communicate with the host device 110 is reduced by disabling one or more pins 126 via configuration data, and the corresponding signals are consolidated via the buffer circuitry of the control circuitry 122. Accordingly, the number of the pins 116 within the corresponding host device 110 may be reduced, reducing the corresponding cost of the host device 110. For a memory IC device 120 in a native configuration, the pins 126 are configured via configuration data to align the pins 126 of the native memory IC device 120 with the pins 116 of the host device 110. Accordingly, a host device 110 may be configured with a reduced number of the pins 116, reducing the design and manufacturing cost of the corresponding semiconductor device. Further, a memory IC device 120 in a native configuration may have the corresponding pins 126 reconfigured accordingly.

In one example, the pins 126 of the memory IC device 120 are configured to improve the performance of the host device 110. In one example, the layout of the pins 126 and configuration of the memory IC device 120 determined based on the layout of the pins 116 and configuration of the host device 110. For example, one or more of the pins 126 of the memory IC device 120 is enabled, disabled, or has a change in functionality based on the pin layout and configuration of the host device 110. In one example, configuration data is loaded into the memory IC device 120 to configure the pins 126.

In one example, the pins 126 are used to communicate signals (e.g., data signals, link protection signals, clock signals, metadata signals, and/or controls signals, among others) to and from the memory IC device 120. In a buffered configuration, the buffer circuitries of the control circuitry 122 are coupled to the pins 126, and then to the host device 110. In a native mode, the memory devices 124 are directly connected to the pins 126, and then to the host device 110. One or more of the pins 126 are configured based on configuration data loaded into the memory IC device 120. Configuring a pin of the pins 126 enables, disables, or alters the use of a pin or signal associated with a pin. In one example, a pin may be configured to communicate clock signals, data signals, link protection signals, metadata signals, and/or controls signals based on the configuration data loaded into the memory IC device 120. Configuration of the memory IC device 120 may occur during manufacturing and/or design of the memory IC device 120. In one example, the configuration of the pins 126 is based on the interface configuration of the memory controller circuitry 114. In an example where the memory controller circuitry 114 is configured to communicate with a buffered memory IC device, the pins 126 are configured accordingly. Further, in an example where the memory controller circuitry 114 is configured to communicate with a native memory IC device, the pins 126 are configured accordingly.

In one example, the pins 126 are configured in a buffer configuration or a native configuration based on a configuration or a setting of the host device 110. For example, based on if the host device 110 supports link protection or does not support link protection, the pins 126 are configured accordingly. Link protection (or memory protection) is used to ensure integrity of transmitted data signal, and other, signals to and from the host device 110. In one or more examples, the link protection signals include using error correction codes and/or detection codes. The error correction codes and/or detection codes are communicated from the host device 110 and used by the memory IC device 120 to determine integrity of the transmitted data signal. In an example where the memory IC device 120 is configured in a buffered configuration, the buffer circuitries of the control circuitry 122 are able to handle the communication of link protection signals, the pins 126 are associated with the link protection signals. In a buffered configuration, the link protection signals are communicated directly to the buffer circuitries of the control circuitry 122, and additional ones of the pins 126 are not needed to handle receiving of the link protection signals. In a native configuration, the link protection signals are communicated to the memory IC device 120 from the host device 110 via one or more of the wires 130 and one or more of the pins 126.

In an example, where the memory IC device 120 is configured in a native configuration, the memory IC device 120 includes four strobe pins per two data pins, and two clock pins per seven address pins. The host device 110 has four strobe pins per eight data pins, and two clock pins per fourteen address pins. Signal muxing may be used by the memory IC device 120 in such a configuration, reducing the number of pins 126 that are used to communicate with the host device 110. For example, one or more of the pins 126 are disabled, and signal muxing is used to support the pin configuration of the host device 110. In memory IC device 120 having a buffered configuration, the buffer circuitry of the control circuitry 122 is used to consolidate the signals within the memory IC device 120 before the signals are communicated to the host device 110. In one or more examples, from the perspective of the host device 110, the signal count of a native memory IC device 120 is similar to that of a buffered memory IC device 120.

In one or more examples, the pins 126 are configured to support different pin ratios or signal ratios. For example, the configuration of the pins 126 may be set to support a higher number of data signal pins to clock signal pins, or a lower number of data signal pins to clock signal pins by enabling, disable, and/or adjusting the functionality of one or more of the pins via configuration data.

In one or more examples, the memory IC device 120 includes one or more channels. A channel has a corresponding one or more of the pins 126 and one or more of the wires 130. The channels may be referred to as pseudo channels. In one example, there are two channels that each has seven corresponding address pins of the pins 126. In one or more examples, the channels are combined. Accordingly, the channels are not associated with independent pins. In one example, the fourteen address pins may be reduced to seven address pins by enabling and/or disabling one or more of the pins 126.

In one or more examples, metadata and link protection signals (error correction codes and/or detection codes) are communicated between the host device 110 and the memory IC device 120. The link protection signals include error correction codes (ECC) and/or cyclic redundancy check (CRC) signals. The signals may be communicated via an in-band communication link or a parallel communication link. In one example for a native memory IC device 120, the CRC pins of interface circuitry 226 are disabled, and the CRC bits (e.g., CRC signals) are consolidated with another signal before being communicated. Accordingly, independent pins of the pins 126 are not used to communicate CRC bits, and one or more of the pins 126 are disabled. In a buffered memory IC device 120, the data is sent in line and to a pin of the pins 126 connected to the buffer circuitry of the control circuitry 122. In such an example, one or more of the pins 126 are used to communicate CRC bits.

In one or more examples, the pins 126 are configured to mitigate pin bandwidth underutilization based on whether the memory IC device 120 is in a buffered configuration or a native configuration. In one example, the host device 110 requires 32 bits of metadata per 512 bits of data. On the memory IC device, 512 bits of data is accessed from one or more memory devices 124 (e.g., 64 bits from 8 memory devices). Accordingly, there are 4 bits of metadata from each of the 8 memory devices. The amount of metadata from each memory device is less than the burst length for a native memory IC device 120. The burst length may be 32 bits. The memory IC device 120 may use one or more of the pins 126 for the metadata that includes 1 bit per 2 data signal or 2 bits per 4 data signal (when shared between pseudo-channels). Accordingly, the pin bandwidth is underutilized and is inefficient as a dedicated one of the pins 116 on the host device 110. In a memory IC device 120 in a buffered configuration, the buffer circuitry of the control circuitry 122 consolidates the metadata from each of the corresponding memory devices 124, and outputs the consolidated metadata via one or more of the pins 126 onto one or more pins 116 of the host device 110. Such a configuration better matches the metadata, CRC signals, and/or ECC, to the size of the corresponding bit burst length, improving the pin bandwidth utilization. In a memory IC device 120 in native configuration, one or more of the pins 126 are disabled and the metadata is transferred by other means (e.g., as the in-line burst-length extension).

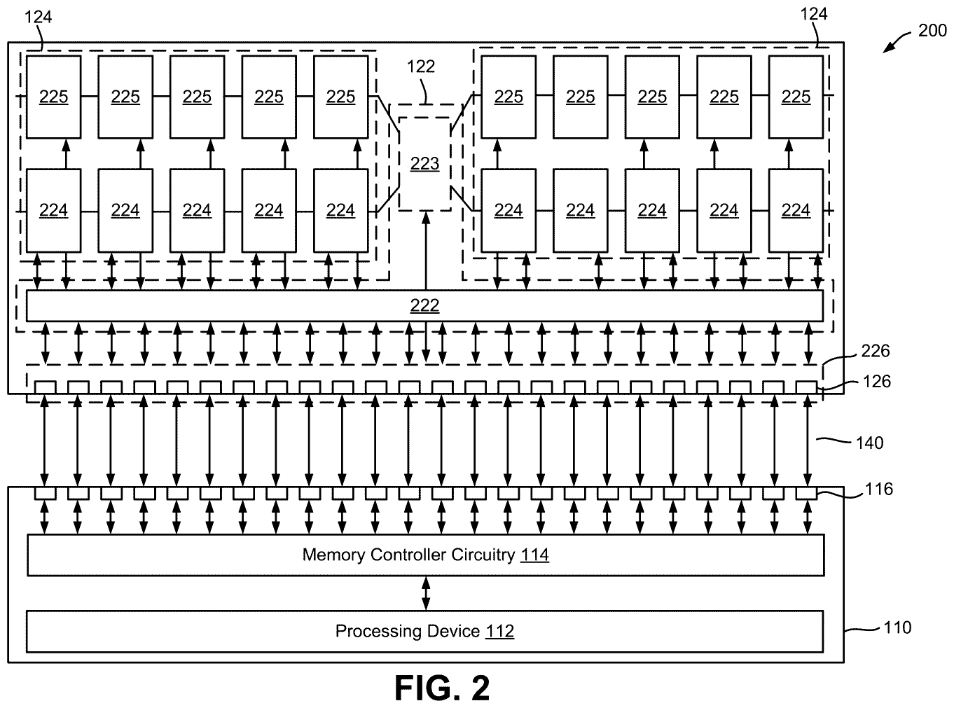

FIG. 2 is a block diagram of an electronic device 200. The electronic device 200 is configured similar to that of the electronic device 100. For example, the electronic device 200 includes the host device 110 and the memory IC device 120. The host device 110 is connected to the memory IC device 120 via the wires 140.

As is illustrated in FIG. 2, the memory devices 124 include the memory devices 224 and 225 are connected to the control circuitry 122. The memory devices 224 are arranged in a first row. The memory devices 225 are arranged in a second row. In other examples, the memory devices 224 and 225 may have other arrangements.

In one example, the memory devices 224 and 225 are disposed on a PCB having a first side and a second side, or a front side and a back side (e.g., two opposite sides) of PCB. In such an example, a first group the memory devices 224 and 225 are disposed on the first side and a second group of the memory devices 224 and 225 are disposed the second side. For example, the memory devices 124 are disposed on a first side and the memory devices 124 are disposed on a second side. Such a configuration may be referred to a DIMM.

The control circuitry 122 includes buffer circuitry 222 and MRCD circuitry 223. In one or more examples, the MRCD circuitry 223 is omitted. In one example, the control circuitry 122 of a memory IC device 120 having a buffered configuration includes the buffer circuitries 222. The buffer circuitries 222 include one or more buffer circuits. In a buffered configuration (e.g., a buffer mode), the memory devices 224 and 225 4 communicate with the host device 110 via the buffer circuitries 222 and/or the MRCD circuitry 118.

In a buffered configuration, the buffer circuitries 222 control the communication of control signals, and/or data signals to the memory devices 224 and 225. The MRCD circuitry 223 buffers the control signals (e.g., command address signals, chip select signals, and clock signals, among others) received from the memory controller circuitry 114. The MRCD circuitry 118 outputs the buffered signals to the buffer circuitries 222 and/or the memory devices 224 and 225.

In a native configuration (e.g., a native mode), the control circuitry 122 of the memory IC device 120 does not include the buffer circuitries 222. Further, in a native configuration, the control circuitry 122 of the memory IC device 120 may additional not include the MRCD circuitry 118. In a native configuration, the memory devices 224 and 225 communicate with the host device 110 directly (e.g., without the use of buffer circuitries 222).

In one example, memory IC device 120 includes interface circuitry 226. The interface circuitry 226 includes pins 126. The pins 126 are input/output pins. The pins 126 that are used to communicate signals (e.g., data signals, link protection signals, clock signals, metadata signals, and/or controls signals, among others) to and from the memory IC device 120. In a buffered configuration, the memory devices 224 and 225 are connected to the buffer circuitries 222, which are connected to the pins 126 of the interface circuitry 226, and then to the host device 110. In a native mode, the memory devices 224 and 225 are directly connected to the pins 126 interface circuitry 226, and then to the host device 110. The pins 126 within the interface circuitry 226 may be configured based on configuration data loaded into the memory IC device 120. Configuring a pin enables, disables, or alters the use of one or more pins 126 or signal associated with one or more pins 126. In one example, configuration data provided to the memory IC device 120, and one or more pins 126 are configured to communicate clock signals, data signals, link protection signals, metadata signals, and/or controls signals based on the configuration data. Configuration of the memory IC device 120 (e.g., configuration data is loaded into the memory IC device 120) occurs during manufacturing and/or design of the memory IC device 120.

In one example, the pins 126 are configured based on the interface configuration of the memory controller circuitry 114. In one example, configuration data is communicated from the memory controller circuitry 114 to the memory IC device 120. The configuration data indicates the interface configuration of the memory controller circuitry 114. For example, the configuration data indicates the memory controller circuitry 114 is configured to communicate with a buffered configured memory IC device or a native configured memory IC device. In an example, where the configuration data indicates that the memory controller circuitry 114 is configured to communicate with a buffered configured memory IC device, the configuration of the pins 126 is determined such that the pins 126 communicate with the buffer circuitries 222. For example, the pins 126 are connected to the buffer circuitries 222. In an example, where the configuration data indicates that the memory controller circuitry 114 is configured to communicate with a native configured memory IC device, the configuration of the pins 126 is determined such that the pins 126 communicate directly with the memory devices 224 and 225, bypassing the buffer circuitries 222. For example, the pins 126 are connected to the memory devices 224 and 225 and not to the buffer circuitries 222.

Further, as is described above, the pins 126 are configured based on a communication protocol and/or security protocol of the memory controller circuitry 114. In such an example, the configuration data provided to the memory IC device 120 includes an indication of the communication protocol and/or security protocol of the memory controller circuitry 114, and the configuration of the pins 126 is determined and set based on the communication protocol and/or security protocol. In one or more examples, the configuration includes an indication associated with the number of data signals, strobe signals, clock signals, and/or address signals used to communicate with the memory controller circuitry 114. The configuration of the pins 126 is determined and set based on the number of data signals, strobe signals, clock signals, and/or address signals. In one example, the configuration data indicates a ratio of data signals to clock signals used by the memory controller circuitry 114. The configuration of the pins 126 is determined and set based on the ratio of data signals to clock signals used by the memory controller circuitry 114. In one example, the configuration data indicates a number of channels used by the memory controller circuitry 114 and/or if any of the channels are shared channels. The configuration of the pins 126 is determined and set based on the number of channels used by the memory controller circuitry 114 and/or if any of the channels are shared channels. In one example, configuring the pins 126 includes reconfiguring one or more of the pins 126 based on configuration data.

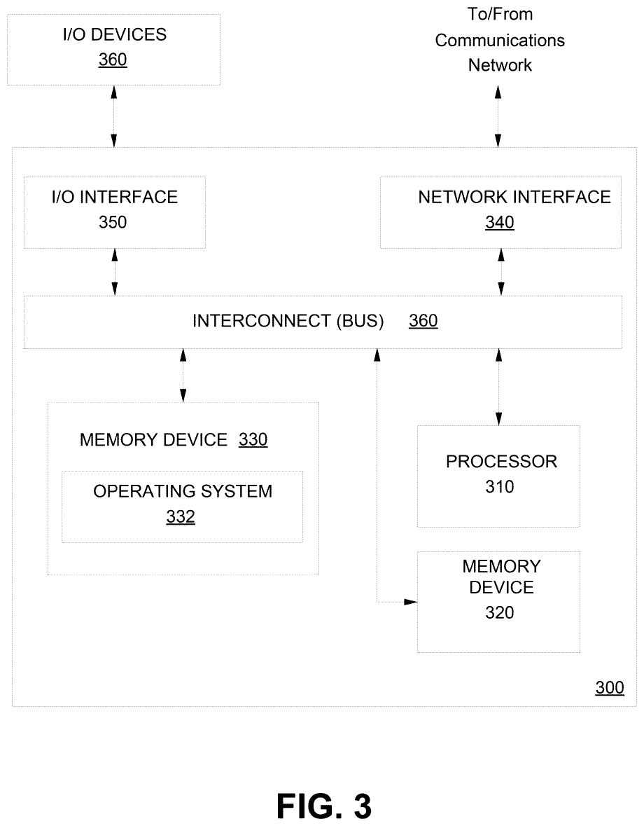

FIG. 3 illustrates a computer system 300 according to one or more examples. As shown, the computer system 300 includes, without limitation, a computer processor 310 (e.g., a central processing unit or a graphics processing unit), a network interface 340, and a memory device 330. The computer system 300 may also include an input/output (I/O) device interface 350 connecting I/O devices 360 (e.g., keyboard, display, and mouse devices) to the computer system 300.

The computer system 300 may be connected (e.g., networked) to other machines (or systems) in a local area network (LAN), an intranet, an extranet, and/or the Internet. The computer system 300 may operate in the capacity of a server or a client machine in client-server network environment, as a peer machine in a peer-to-peer (or distributed) network environment, or as a server or a client machine in a cloud computing infrastructure or environment.

In one or more examples, the computer system 300 may be a personal computer (PC), a mobile computing device (e.g., tablet or a mobile phone device), or any computer system capable of executing a set of instructions (sequentially or otherwise) that specify actions to be taken by that computer system. Further, while a single computer system 300 is illustrated, in other examples, the computer system 300 includes any collection of machines that individually or jointly execute a set (or multiple sets) of instructions to perform any one or more of the methodologies discussed herein.

In one or more examples, the computer processor 310 retrieves and executes programming instructions stored in the memory device 330 (e.g., a non-transitory computer readable medium) for performing the operations and steps described herein. Similarly, the computer processor 310 stores and retrieves application data residing in the memory device 330. An interconnect circuitry (bus) 360 facilitates transmission, such as programming instructions and application data, between the computer processor 310, I/O device interface 350, memory device 320, network interface 340, and memory device 330. The computer processor 310 corresponds to the host device 110 of FIG. 1. For example, the computer processor 310 includes memory controller circuitry 114 and the pins 116. The computer processor 310 is included to be representative of a single processor, multiple processors, a single processor having multiple processing cores, and the like. Further, the memory device 330 and the memory device 320 are generally included to be representative of volatile and non-volatile memory elements. For example, the memory device 330 and the memory device 320 can include random access memory and a disk drive storage device. Although shown as a single unit, the memory device 330 or the memory device 320 may be a combination of fixed and/or removable storage devices, such as magnetic disk drives, flash drives, removable memory cards or optical storage, network attached storage (NAS), or a storage area-network (SAN). The memory device 320 may include both local storage devices and remote storage devices accessible via the network interface 340. In one example, the memory device 320 corresponds to the memory IC device 120 of FIG. 1.

As shown, the memory device 330 includes an operating system 332. The operating system 332 may facilitate receiving input from and providing output to various components. The operating system 332 includes a user interface that displays information within a display device. Further, the user interface may include one or more input elements that receive input from a user.

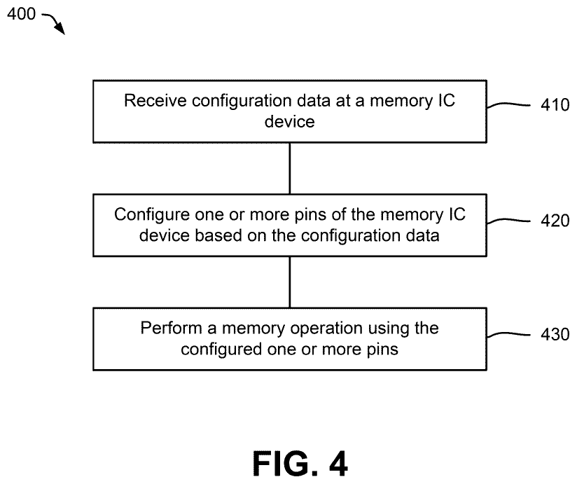

FIG. 4 illustrates a flowchart of a method 400 for configuring pins of a memory IC device. In one example, the method 400 is performed at least in part by the memory IC device 120 of FIG. 1.

At operation 410 of the method 400, configuration data is received by a memory IC device. For example, the configuration data is received by the memory IC device 120 of FIG. 1. In one or more example, the configuration data is received during design or test of the memory IC device 120 and/or the electronic device 100 of FIG. 1. In one example, the configuration data is generated by the host device 110 of FIG. 1, and output to the memory IC device 120. The configuration data may be sent by the host device 110 when the host device 110 is connected to the memory IC device 120, or based on another triggering event. In one example, the configuration data is sent based on a programming or reprogramming of the memory IC device 120 and/or the host device 110. The configuration data is sent as a signal comprising a plurality of data bits. In one or more examples, the configuration data indicates a communication protocol and/or security protocol of the memory controller circuitry 114. In one or more examples, the configuration includes an indication associated with the number of data signals, strobe signals, clock signals, and/or address signals used to communicate with the memory controller circuitry 114. In one example, the configuration data indicates a ratio of data signals to clock signals used by the memory controller circuitry 114. In one example, the configuration data indicates a number of channels used by the memory controller circuitry 114 and/or if any of the channels are shared channels.

At operation 420 of the method 400, one or more pins of the memory IC device are configured based on the configuration data. In one example, one or more of the pins 126 are configured based on the configuration data. In one example, the one or more pins of the pins 126 are reconfigured based on whether the memory IC device 120 is to be configured as a buffered configured memory IC device or a native configuration memory IC device. The one or more of the pins 126 is reconfigured as is described above.

At operation 430 of the method 400, a memory operation is performed using the configured one or more pins. In one example, the configured pins 126 are used to receive and/or communicate data signals to and/or from the memory IC device 120. For example, data to be written to the memory IC device 120 is communicated from the memory controller circuitry 114 using the configured pins 126 of the memory IC device 120. Further, data is read from the memory IC device 120 by the memory controller circuitry 114 using the configured pins 126 of the memory IC device 120.

Input/output pins of memory IC device are configurable to support various operation modes of the memory IC device and/or a corresponding host device. Configuring the pins includes enabling one or more of the pins, disabling one or more of the pins, connecting one or more of the pins with buffer circuitries of the memory IC device, connecting one or more of the pins directly with memory devices of a memory IC device, changing a functionality of one or more pins, and/or adjusting a signal received by one or more of the pins. Accordingly, one or more pins can be used for different functions/tasks, allowing for a memory IC device to support different operating modes (e.g., native configuration or buffered configuration) and/or differently configured host devices, reducing the semiconductor manufacturing and design costs associated with the memory IC device.

In one or more examples, a memory integrated circuit (IC) device includes memory devices and pins connected to the memory devices. The pins route signals to and from the memory devices. The pins are configurable based on configuration data to perform memory operations. In one example, the pins are directly connected with the memory devices based on the configuration data indicating that the memory IC device is in a native configuration. In one example, the memory IC device further includes buffer circuitries connected to the memory devices. The pins are connected to the buffer circuitries based on the configuration data indicating that the memory IC device is in a buffered configuration. In one or more examples, the pins are configurable by at least one of enabling one or more of the pins or disabling one or more of the pins based on the configuration data. In one or more examples, the pins are configurable by changing a functionality of one or more of the pins. In one or more examples, the pins are coupled to a host device via wires. The configuration data indicates a protocol of the host device. In one or more examples, the configuration data is received from the host device.

In one example, an electronic device includes a host device comprising memory controller circuitry and a memory IC device connected to the memory controller circuitry. The memory IC device includes memory devices and pins connected to the memory devices and the memory controller circuitry. The pins route signals to and from the memory devices. The pins are configurable based on configuration data to perform memory operations. In one example, the pins are directly connected with the memory devices based on the configuration data indicating that the memory IC device is in a native configuration. In one example, the memory IC device further comprises buffer circuitries connected to the memory devices. The pins are connected to the buffer circuitries based on the configuration data indicating that the memory IC device is in a buffered configuration. In one example, the pins are configurable by at least one of enabling one or more of the pins or disabling one or more of the pins based on the configuration data. In one example, the pins are configurable by changing a functionality of one or more of the pins. In one example, the configuration data indicates a protocol of the host device. In one example, the host device communicates the configuration data to the memory IC device.

In one example, a method includes receiving, at a memory IC device, configuration data for one or more pins of the memory IC device. The pins are connected to memory devices of the memory IC device and route signals to and from the memory devices. The method further includes configuring one or more of the pins based on the configuration data. Further, the method includes performing a memory operation using the configured one or more pins. In one example, configuring one or more of the pins comprises directly connecting one or more of the pins with the memory devices based on the configuration data indicating that the memory IC device is in a native configuration. In one example, configuring one or more of the pins comprises connecting one or more of the pins to buffer circuitries of the memory IC device based on the configuration data indicating that the memory IC device is in a buffered configuration, wherein the buffer circuitries are connected to the memory devices. In one example, configuring one or more of the pins comprises at least one of enabling one or more of the pins or disabling one or more of the pins based on the configuration data. In one example, configuring one or more of the pins comprises changing a functionality of one or more of the pins. In one example, the pins are coupled to a host device via wires. The configuration data indicates a protocol of the host device, and wherein the configuration data is received by the memory IC device from the host device.

While the foregoing is directed to specific examples, other and further examples may be devised without departing from the basic scope thereof, and the scope thereof is determined by the claims that follow.

What is claimed is:

1. A memory integrated circuit (IC) device comprising:
memory devices; and
pins connected to the memory devices and configured to route signals to and from the memory devices, wherein the pins are configurable based on configuration data to perform memory operations.

2. The memory IC device of claim 1, wherein the pins are directly connected with the memory devices based on the configuration data indicating that the memory IC device is in a native configuration.

3. The memory IC device of claim 1, further comprising buffer circuitries connected to the memory devices, and wherein the pins are connected to the buffer circuitries based on the configuration data indicating that the memory IC device is in a buffered configuration.

4. The memory IC device of claim 3, wherein one or more of the buffer circuitries is configured to consolidate data from two or more of the memory devices, and the consolidated data is output via one of the pins.

5. The memory IC device of claim 1, wherein the pins are configurable by at least one of enabling one or more of the pins or disabling one or more of the pins based on the configuration data.

6. The memory IC device of claim 1, wherein the pins are coupled to a host device via wires, and wherein the configuration data indicates a protocol of the host device.

7. The memory IC device of claim 6, wherein the configuration data is received from the host device.

8. An electronic device comprising:
a host device comprising memory controller circuitry, and
a memory integrated circuit (IC) device connected to the memory controller circuitry, the memory IC device comprising:
memory devices; and
pins connected to the memory devices and the memory controller circuitry and configured to route signals to and from the memory devices, wherein the pins are configurable based on configuration data to perform memory operations.

9. The electronic device of claim 8, wherein the pins are directly connected with the memory devices based on the configuration data indicating that the memory IC device is in a native configuration.

10. The electronic device of claim 8, wherein the memory IC device further comprises buffer circuitries connected to the memory devices, and wherein the pins are connected to the buffer circuitries based on the configuration data indicating that the memory IC device is in a buffered configuration.

11. The electronic device of claim 10, wherein one or more of the buffer circuitries is configured to consolidate data from two or more of the memory devices, and the consolidated data is output via one of the pins.

12. The electronic device of claim 8, wherein the pins are configurable by at least one of enabling one or more of the pins or disabling one or more of the pins based on the configuration data.

13. The electronic device of claim 8, wherein the configuration data indicates a protocol of the host device.

14. The memory IC device of claim 8, wherein the host device is configured to communicate the configuration data to the memory IC device.

15. A method comprising:
receiving, at a memory integrated circuit (IC) device, configuration data for one or more pins of the memory IC device, wherein the pins are connected to memory devices of the memory IC device and configured to route signals to and from the memory devices;
configuring one or more of the pins based on the configuration data; and
performing a memory operation using the one or more configured pins.

16. The method of claim 15, wherein configuring one or more of the pins comprises directly connecting one or more of the pins with the memory devices based on the configuration data indicating that the memory IC device is in a native configuration.

17. The method of claim 15, wherein configuring one or more of the pins comprises connecting one or more of the pins to buffer circuitries of the memory IC device based on the configuration data indicating that the memory IC device is in a buffered configuration, wherein the buffer circuitries are connected to the memory devices.

18. The method of claim 17, wherein one or more of the buffer circuitries is configured to consolidate data from two or more of the memory devices, and the consolidated data is output via one of the pins.

19. The method of claim 15, wherein configuring one or more of the pins comprises at least one of enabling one or more of the pins or disabling one or more of the pins based on the configuration data.

20. The memory IC device of claim 1, wherein the pins are coupled to a host device via wires, wherein the configuration data indicates a protocol of the host device, and wherein the configuration data is received by the memory IC device from the host device.
